(19) United States
(12) Patent Application Publication
(10) Pub. No.: US 2025/0357709 A1
(43) Pub. Date: Nov. 20, 2025

(54) PLUG CONNECTOR PART FOR A HOUSING OF A CONTROL DEVICE, HOUSING FOR A CONTROL DEVICE OF A VEHICLE, CONTROL DEVICE FOR A VEHICLE HAVING SUCH A HOUSING AND VEHICLE HAVING A CONTROL DEVICE

(71) Applicant: ZF CV Systems Global GmbH, Bern (CH)

(72) Inventors: Thomas Bolik, Hannover (DE); Tobias Koch, Hannover (DE); Tobias Wustrack, Barsinghausen (DE)

(21) Appl. No.: 19/288,844

(22) Filed: Aug. 1, 2025

Related U.S. Application Data
(63) Continuation of application No. PCT/EP2024/051113, filed on Jan. 18, 2024.

(30) Foreign Application Priority Data
Feb. 14, 2023 (DE) 10 2023 103 516.9

(51) Int. Cl. H01R 13/74; H01R 13/04; H05K 5/00; H05K 5/04

(52) U.S. Cl. CPC H01R 13/74; H01R 13/04; H05K 5/0052; H05K 5/0069; H05K 5/04

(57) ABSTRACT

A plug connector part is configured for cooperating with at least one housing part. The plug connector part and the at least one housing part are configured to form a housing for a control device for vehicles. The control device has control elements connected together in a signal-conducting manner for controlling functions of the vehicle. The plug connector part has one or more plug connectors for signal lines and a contact region extending along at least one portion of the plug connector part and is configured for the sealed connection to the housing part. The plug connector part also has at least one connector structure arranged on the inner face thereof defining an interior of the housing and configured to hold the plug connector part in position relative to the housing part via retainers arranged on the housing part or which can be connected to the housing part.

### CROSS-REFERENCE TO RELATED APPLICATIONS

This application is a continuation application of international patent application PCT/EP2024/051113, filed Jan. 18, 2024, designating the United States and claiming priority from German application 10 2023 103 516.9, filed Feb. 14, 2023, and the entire content of both applications is incorporated herein by reference.

### TECHNICAL FIELD

The present disclosure relates to a plug connector part which is configured for cooperating with at least one housing part, in particular a housing part made of metal or plastics, wherein the plug connector part and the at least one housing part are configured to form a housing for a control device for vehicles, in particular for vehicle components of a vehicle, wherein the control device has a plurality of control elements which are connected together in a signal-conducting manner for controlling functions of the vehicle, wherein the plug connector part has one or more plug connectors for signal lines to be coupled thereto, and a contact region which extends along at least one portion of the plug connector part and which is configured for connection to the housing part, in particular for the positive and/or sealed connection to the housing part.

The disclosure further relates to a housing for a control device for vehicles, in particular for vehicle components of a vehicle, a control device for a vehicle, in particular for vehicle components of a vehicle and a vehicle, in particular a passenger motor vehicle or utility vehicle.

### BACKGROUND

Known control devices for vehicles, such as for example engine control units or brake or transmission control units, are used for controlling the functions on a vehicle, in particular the different vehicle components of the vehicle. The known control devices frequently include a plurality of control elements which are connected together in a signal-conducting manner, the different functions and operating states being able to be implemented thereby on, for example, a vehicle engine, a brake device or a transmission. The control devices generally include a housing which receives the control elements and which can be at least partially configured from metal. A region of the housing surrounding the control elements is defined by a plug connector part, also denoted as a header, on which at least one plug connector, which is configured in particular as a plug interface, is present for a signal line to be coupled thereto. The plug connector part also has a contact region which extends at least along a portion of the plug connector part and which is configured for connection to the housing part.

On the control devices known from the prior art, a structural coupling between the housing part and the plug connector part is also implemented via the sealed connection, frequently an adhesively bonded connection. In particular in the case of forces acting unfavorably on the plug connector part or the header, for example produced due to the control lines connected to the plug connector part, it can lead to a partial failure of the adhesively bonded connection which often also leads to a failure of the sealing action of the adhesively bonded connection. With the failure of the sealing function, moisture can penetrate into the interior of the control device which often leads to a malfunction of the control device itself and thus to a fault in the vehicle.

### SUMMARY

It is an object of the disclosure to specify a plug connector part, a housing and a control device in which the above-described drawbacks are avoided. In particular, the object of the invention was to specify a plug connector part, a housing and a control device on which the structural load on the adhesively bonded connection is at least reduced, ideally avoided, and thus a permanently secure sealing function can be ensured.

The object is, for example, achieved by a plug connector part according to various embodiments of the disclosure. The disclosure is based on a plug connector part mentioned in the introduction and provides according to the disclosure that at least one connector structure is provided on the plug connector part, which connector structure is arranged on the inner face thereof defining an interior of the housing and is configured to hold the plug connector part in position relative to the housing part via holding means which are arranged on the housing part or which can be connected to the housing part.

The disclosure is characterized in that a connector structure which is configured separately from the contact region is provided on the plug connector part, additionally a structural coupling is provided thereby between the plug connector part, also denoted as a header, and the housing part which is made of, in particular, metal or plastics and which generally receives the plug connector part. Forces which act on the plug connector part, for example via the signal lines which during the operation of the control device are connected to the plug connector of the plug connector part, are now absorbed via the connector structure, instead of via the adhesively bonded connection, and introduced into the housing part which can be connected to the plug connector part. Due to the connector structure which is arranged on the inner face of the plug connector part, the forces which act on the sealed connection are significantly reduced, ideally entirely eliminated, in comparison with the known embodiments. Preferably, an adhesively bonded connection which acts free of forces is formed between the plug connector part and the housing part, in particular a permanent sealing action being possible thereby. The inner face of the plug connector part, on which the connector structure is arranged, defines the interior of the housing of the control device within which the control elements thereof are arranged.

In the present case a plug connector, to which a signal line is connected in the operating state of the control device, can be a plug, such as for example a pin contact strip, or can be configured as a plug socket, correspondingly configured plug connectors accordingly being coupled thereby for the signal-conducting transmission.

In an embodiment, the plug connector part has a wall portion which defines a part of the housing, wherein the plug connector(s) is/are arranged on the outer face of the wall portion and the connector structure is arranged on the inner face of the wall portion. The wall portion of the plug connector part preferably forms regions of the wall of the housing surrounding the control elements and thus the electronics of the control device. The wall portion, which in one possible embodiment forms at least one planar surface region of the plug connector part, on the one hand separates the outer face from the inner face of the plug connector part, which faces are located in particular on surface regions of the wall portion facing away from one another. On the other hand, the elements are arranged on the surface regions of the wall portion facing away from one another, namely the plug connector(s) on the outer face and the at least one connector structure on the inner face, forces being applied thereby to the plug connector part and diverted into the housing part which can be coupled to the plug connector part, whereby in the assembled state the plug connector part is held fixedly in position on the housing part. A deformation on the plug connector part, due to the forces acting thereon, is advantageously avoided.

With the provision of a wall portion on the plug connector part, an advantageous possibility is also implemented for configuring a contact region which can be brought to bear against the housing part. Preferably, the contact region is configured at least along a portion of the periphery of the wall portion. According to an embodiment, the contact region on the plug connector part is produced in a peripheral manner along the periphery of its wall portion. The contact region on the plug connector part can be brought to bear against one or more housing parts for forming the housing.

Preferably, a plurality of connector structures are arranged on the inner face of the plug connector part, wherein the connector structure is preferably configured as a holder or socket protruding on the inside. A more uniform force distribution over a larger region on the inner face of the plug connector part is possible via a plurality of such connector structures arranged on the inner face of the plug connector part, in particular on the inside wall portion thereof. A point-based structural load on the plug connector part is further reduced, which has an advantageous effect on the dimensional stability of the plug connector part. Preferably, at least two, three or more such connector structures are arranged on the inner face of the plug connector part, in particular on the inner face of the wall portion thereof. In one possible embodiment, the plurality of connector structures are arranged so as to be distributed at a uniform spacing along, for example, the length of the plug connector part.

In one possible embodiment, the connector structures are configured as a holder or socket which protrudes on the inside and which can be coupled in a simple manner to corresponding holding means accordingly arranged on the housing part or able to be connected to the housing part. Preferably, the connector structure is configured as a socket with which, for example, a bolt protruding from a housing part or a fastening pin, for example in the form of a screw, which can be retrospectively passed through after the assembly of the housing, cooperates. A holding means which is configured as a screw penetrates, for example, the connector structure which is configured as a socket and is fastened with its end opposing the head with a threaded portion in a threaded blind bore of a fastening projection on one of the housing parts. In an alternative or optional embodiment, one respective connector structure, which is configured as a holder and which, for example, has a web portion protruding perpendicularly to the plug connector part, for example a cylindrical projection being arranged on the end thereof, engages in correspondingly configured recesses accordingly on a housing part or on the plurality of housing parts. The connector structures which are configured on the inner face of the plug connector part can have any configuration/shape, provided this is suitable for forming a positive connection between the connector structure on the plug connector part and a holding means which is arranged on the housing part or which can be connected to the housing part.

According to an embodiment of the disclosure, the connector structure is configured in one piece with the plug connector part, in particular the connector structure is injection-molded onto the plug connector part, also denoted as a header. With the one-piece or even integral embodiment of the plug connector part, a permanently fixed connection between the connector structure and the adjacent regions of the plug connector part achieves a reliable transmission of forces. In an embodiment, the connector structure is injection-molded onto the plug connector part, so that the connector structure is directly produced thereon when manufacturing the plug connector part.

In an embodiment of the disclosure, the plug connector part has a peripheral indentation with a constant width dimension along the contact region, for the sealed connection to be formed with the housing part, in particular the adhesively bonded connection. Due to the constant width of the indentation, a uniform connection is achieved along the entire contact region between the plug connector part and the at least one housing part which can be brought into contact therewith. Portions or regions in which reduced binding forces act, due to an increased accumulation of adhesive between the components to be connected together, are advantageously avoided.

Preferably, the indentation is configured along the periphery of the wall portion of the plug connector part, which further simplifies bringing the plug connector part to bear against the one housing part or the plurality of housing parts, for example with a housing lower part and/or a housing cover, to form the housing. In addition, the embodiment of the indentation with a constant width provides the advantage that with such a positive connection of constant width the same quantity of adhesive per unit of length of the indentation has to be dispensed in a peripheral manner into the indentation for ensuring a sealed connection to the housing part—that is, a sealing function primarily for an adhesively bonded connection.

According to an embodiment of the disclosure, the indentation is configured in a groove-like manner and has two side walls extending parallel to one another over the length thereof at a uniform spacing, and a bottom surface running approximately perpendicularly thereto. A structurally simple embodiment of, in particular, a peripheral indentation with a constant width on the plug connector part is achieved via two side walls running, in particular, along the entire indentation, preferably parallel to one another. The introduction of adhesive for producing the adhesively bonded connection between the plug connector part and the at least one housing part, which can be brought into contact with the plug connector part, is also simplified by the groove-like embodiment. The depth dimension of the groove-like indentation is determined, in particular, by the bottom surface preferably running perpendicularly to the side walls. The width of the bottom surface or the spacing between the side walls running parallel to one another in the present case defines the width dimension of the indentation. Preferably, the indentation also has arcuate portions in the direction of extension, in addition to its portions running linearly, whereby a gradual change of direction is achieved in the path of the contact region and thus an improved connection between the contact surfaces to be joined together.

Preferably, starting from the bottom surface, the internal side wall of the indentation has a smaller vertical dimension in comparison with the external side wall. Due to the shortened internal side wall, when bringing the plug connector part into contact with at least one housing part, it is achieved that excess adhesive located in the indentation escapes in the direction of the inner face of the housing. When forming the housing, therefore, soiling is avoided on the outer face thereof which simplifies the assembly. Moreover, due to the side walls of different heights, a housing part to be brought into contact with the plug connector part can terminate flush with the upper edge of the plug connector part and this permits a flat configuration of the housing. Preferably, the vertical dimension of the internal side wall is reduced by approximately a quarter to approximately a third relative to the vertical dimension of the external side wall.

An embodiment of the disclosure provides that a reinforcing structure is provided on the plug connector part, wherein the reinforcing structure preferably extends along at least one portion of a side edge of the wall portion. An additional strengthening is produced on the plug connector part via the reinforcing structure, in addition to the connector structures on the inner face of the plug connector part. The deformation resistance of the plug connector part is improved thereby. The reinforcing structure runs partially on the outer face and on the inner face of the plug connector part and preferably reinforces the wall portion, in particular a large-area flat central wall part on the plug connector part. Parts of the housing delimiting the wall in its external dimensions are defined via the reinforced wall portion. Preferably, at least two reinforcing structures, which are arranged at a spacing from one another, are provided on the plug connector part, the deformation resistance of the plug connector part being further increased thereby.

In an embodiment of the disclosure, the reinforcing structure is configured as a material web receiving the indentation and protruding on the outside and/or inside laterally on the wall portion. Preferably, the reinforcing structure acts in combination with an indentation or the indentation which is configured on the periphery of the plug connector part. Specific regions, for example on the wall portion of the plug connector part, which are subjected to an increased risk of deformation perpendicular to the plane of the wall portion, are additionally reinforced.

In one possible embodiment, the plug connector part has a central wall part receiving the plug connector(s). Adjoining the central wall part at opposing ends are two wall end pieces which run at an angle thereto and which protrude from the surface defining the inner face of the wall portion. Preferably, connecting radii are provided in the deflection region between the central wall portion and the wall end pieces. In combination with the reinforcing structure preferably running along the longitudinal sides of the central wall part and the wall end pieces, the plug connector part has a preferably reinforced corner geometry which advantageously acts on the deformation resistance of the plug connector part.

In a further aspect, the present disclosure relates to a housing for a control device for vehicles, in particular for vehicle components of a vehicle. Such a housing is used, for example, in order to house control electronics, for example for a vehicle component, in a sealed manner relative to external environmental conditions.

The housing according to the disclosure achieves the object forming the basis of the plug connector part by the housing including a plug connector part according to one of the above-described developments or embodiments and also at least one housing part which is made, in particular, of metal, cooperating with the plug connector part, wherein the housing part has at least one holding means which cooperates with the connector structure on the plug connector part for holding the plug connector part in position relative to the housing part. A structural coupling of the housing part and plug connector part to one another takes place via such a housing which is configured according to the disclosure and which cooperates via its holding parts with the connector structures provided on the plug connector part, so that possible forces acting on the plug connector part, in particular on the wall portion of the plug connector part, can be safely absorbed by the connector structure(s) configured on the inner face of the plug connector part and can be diverted into the housing part via the holding means on the housing part. A structural load on the sealed connection produced in the contact region between the at least one housing part and the plug connector part is avoided by the connector structure which is additionally formed on the inside on the plug connector part and the holding means on the housing part cooperating therewith.

An embodiment of the housing provides that the housing part has a projection running along its contact region and cooperating with the indentation on the plug connector part. Preferably, the housing part engages, via its projection running along its contact region, in the indentation on the plug connector part and comes into contact with the adhesive which has been, in particular, previously introduced into the indentation on the plug connector part to form the sealed connection. Once the adhesively bonded connection hardens, a sealing function is produced in the contact region of the plug connector part and the housing part. Due to the connector structures on the inner face of the plug connector part and the holding means cooperating therewith, the sealed connection, in particular the adhesively bonded connection, is ideally free of forces acting thereon.

The housing for a control device makes use of the same advantages and embodiments as the plug connector part according to the disclosure, which together with at least one housing part is configured to form the housing for a control device for vehicles.

In a third aspect, the disclosure relates to a control device for a vehicle, in particular for vehicle components of a vehicle, having a plug connector part according to the disclosure and control elements which are connected to one another in a signal-conducting manner inside the housing, for controlling functions of the vehicle, wherein the control elements are preferably arranged on a printed circuit board.

Yet another aspect of the disclosure relates to a vehicle, in particular a passenger motor vehicle or utility vehicle, having at least a plug connector part.

The embodiments and developments, which are described relative to the plug connector part or the housing, are at the same time also embodiments or developments of the control device according to the disclosure for a vehicle or a vehicle, in particular a passenger motor vehicle or a utility vehicle itself. The control device and the vehicle make use of the same advantages as the plug connector part according to the disclosure or the housing according to the disclosure.

### BRIEF DESCRIPTION OF DRAWINGS

The invention will now be described with reference to the drawings wherein:

FIG. 1 shows a perspective view of a housing with a plug connector part according to the disclosure and two housing parts in an exploded view;

FIG. 2 shows a plan view of a plug connector part according to the disclosure with the housing parts removed therefrom;

FIG. 3 shows a perspective view of the control device according to the disclosure with the housing cover removed, from its inner face in an exploded view; and,

FIG. 4 shows a schematic view of a vehicle with a control device according to FIG. 3.

### DETAILED DESCRIPTION

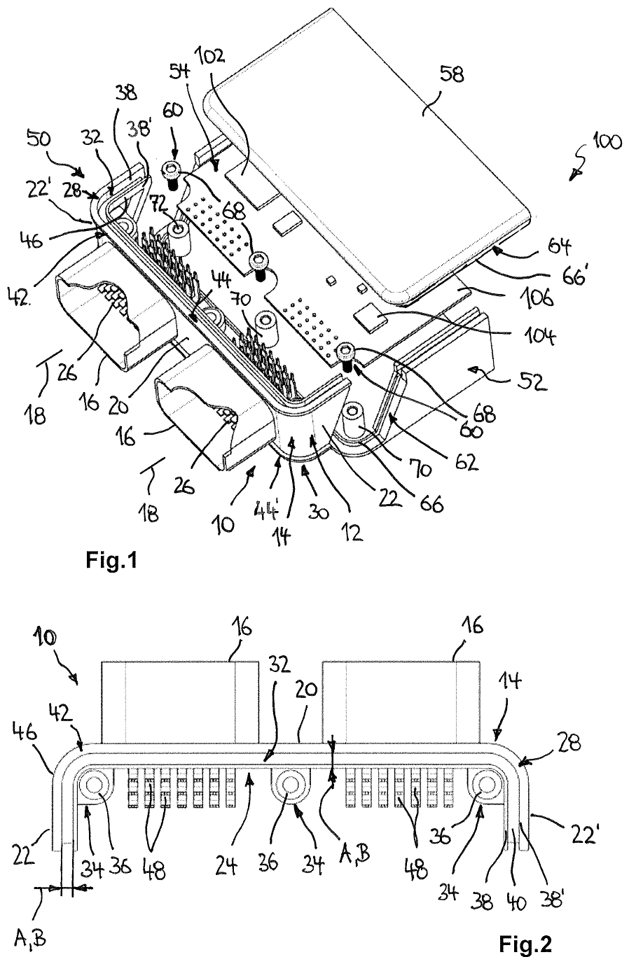

FIG. 1 shows a housing 50 for a control device 100 for vehicles 200 (FIG. 4) which has a wall 52 for forming an interior 54 which is sealed from the environment for control elements 102, 104 which are arranged on a printed circuit board 106 and connected together. The housing 50 is configured, in particular, from a plug connector part 10 according to the disclosure and two housing parts 56, 58 cooperating with the plug connector part 10. The housing parts 56, 58 consist, in particular, of metal or plastics, wherein in the present embodiment at least one, in the present case three, holding means/retainer 60 is/are fastened to the housing part 56 configured as the housing lower part, which holding means are preferably configured as screws 68 and cooperate with the plug connector part 10 in order to hold the plug connector part 10 in position relative to the housing parts 56, 58.

The plug connector part 10, also denoted as a header, has a wall portion 12 which is part of the wall 52 of the housing 50. Two plug connectors 16 for signal lines 18, shown schematically, to be coupled thereto are arranged on an outer face 14 of the wall portion 12.

The wall portion 12 of the plug connector part 10 is formed, in particular, from a central wall part 20 and wall end pieces 22, 22′. The wall end pieces 22. 22′ run at an angle ranging from 30° to 150° to the central wall part 20. In the embodiment shown, the wall end pieces 22, 22′ run on the wall part 20, in each case at an angle of approximately 90°, starting from its inner face 24 which at the same time is also the inner face of the plug connector part 10.

The plug connectors 16 in the embodiment shown are configured in the present case as plugs 26. The signal lines 18 cooperating therewith accordingly have corresponding plug sockets at their ends, not shown in more detail, for cooperating with the plug connectors 16 which are configured, in particular, as plugs 26.

The plug connector part has a contact region 28 which is configured to correspond, in particular in a sealed manner, with contact regions 62, 64 on the housing parts 56, 58—provided the contact regions 28, 62, 64 can be positively connected for closing the housing. The contact region 28 on the plug connector part 10 in the present case has a peripheral indentation 32 along the periphery of the plug connector part 10. The contact regions 62, 64 on the housing parts, in particular on the housing lower part 56, and the housing cover 58, in the present case have in each case material projections 66, 66′ in each case cooperating with the indentation 32 on the plug connector part 10; in this respect the connection is sealingly formed via the contact regions 28, 62, 64.

FIG. 2 shows a plan view of the plug connector part according to the disclosure, in particular on the inner face 24 thereof. As FIG. 2 illustrates, the plug connector part 10 on the inner face 24 which, together with the housing lower part 56 and the housing cover 58, defines the interior 54 of the housing 50, has at least one, in the present case three, connector structures 34. The connector structure 34, in particular the plurality of connector structures 34, is/are configured to hold the plug connector part 10 in position relative to at least one of the housing parts 56, 58 via holding means 60 which are arranged on the housing part 56, 58 or which can be connected to the housing part 56, 58. The connector structures 34 are arranged on the inner face 24 of the wall portion 12. The connector structures 34 are configured as a socket 36 in the embodiment shown. Any embodiments of the connector structures 34 are conceivable, for example also as a holder protruding from the inner face 24 of the plug connector part 10.

The connector structures 34 are configured in one piece with the plug connector part 10. The connector structures 34 are injection-molded, in particular, onto the plug connector part 10 on the inner face 24 thereof; the connector structures 34 are thus produced during the manufacture of the plug connector part 10, also denoted as a header.

As FIG. 2 also shows, the indentation 32 has a constant width dimension B as the contact region 28 on the periphery around the plug connector part. The indentation 32 is configured in a groove-like manner and has two side walls 38, 38′ extending parallel to one another over, in particular, the entire length thereof at a uniform spacing A. The width dimension B corresponds in the present case to the spacing A. In addition, the indentation 32 has a bottom surface 40 running approximately perpendicularly to the side walls 38, 38′. Alternatively, in an embodiment which is not shown, the bottom of the indentation 32 can be configured to be semi-circular. The internal side wall 38′ has a smaller vertical dimension H in comparison with the external side wall 38.

This avoids the external leakage of an adhesive to be introduced into the indentation for producing the sealed connection, in particular the material connection, between the plug connector part 10 and the housing parts 56, 58 to be brought into contact therewith.

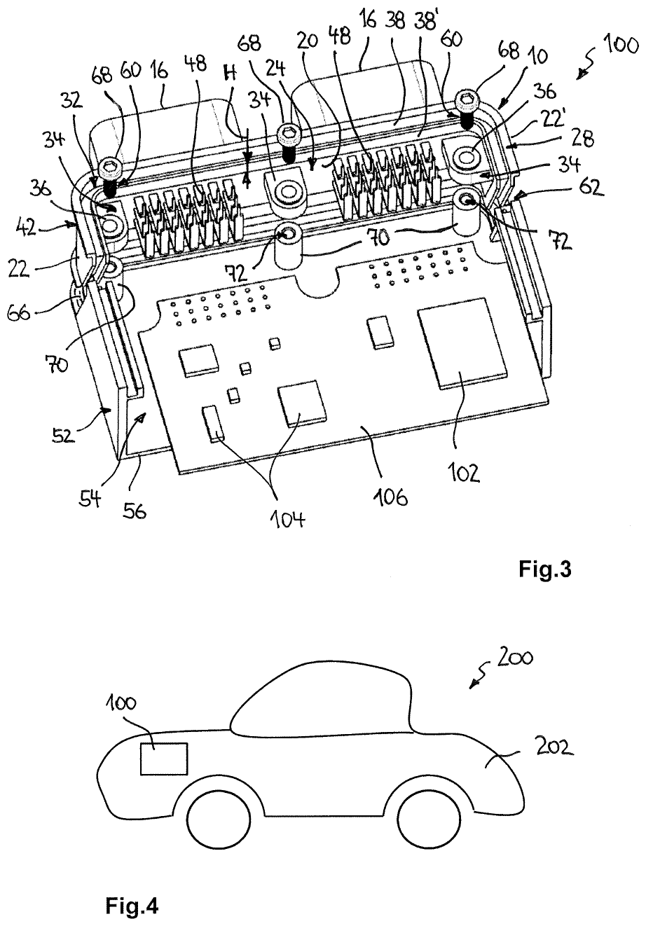

In the embodiment shown in the present case and which is, in particular, visible from FIG. 1 and FIG. 3, the plug connector part 10 has a reinforcing structure 42 which extends along at least one portion of a side edge 44, 44′ of the wall portion 12. The reinforcing structure 42 is produced, in particular, in the region of the indentation 32 which is configured in a peripheral manner on the wall portion 12. The reinforcing structure 42 forms a peripheral material thickening on the periphery 30 of the wall portion 12 and is configured, in particular, as a material web 46 protruding approximately perpendicularly on the outside and/or inside. The peripheral indentation 32 is incorporated with a constant width into the material web 46, which protrudes, in particular, in a peripheral manner from the inner face 24 of the plug connector part 10 and protrudes on the outside only from the side edges 44, 44′.

A perspective view of a control device 100 according to the disclosure is shown in FIG. 3, which control device has a housing 50 having the plug connector part 10 and the housing parts 56, 58 (the housing part 58 not being illustrated, for simplicity) and a plurality of control elements 102, 104 which are connected together in a signal-conducting manner inside the housing 50, for controlling functions of the vehicle 200, in particular the function of vehicle components of the vehicle 200. In the embodiment shown in the present case, the control elements 102, 104 are arranged on a printed circuit board 106. In the embodiment shown in the present case, the electrical connection of the printed circuit board 106 to the terminals 48 of the plug connectors 16 protruding from the inner face 24 of the plug connector part for the signal-conducting transmission, is not shown in detail.

FIG. 3 illustrates the cooperation of the holding means 60 with the housing lower part 56, which holding means are arranged thereon or can be connected to the housing part 56, and with the connector structures 34 configured on the inner face 24 of the wall portion 12. The holding means 60 which are preferably configured as bolts, pins, preferably as screws 68, penetrate the connector structures 34, which are configured in particular as a socket 36, and secure the plug connector part 10 relative to and on at least one of the housing parts 56, 58 of the housing 50. The holding means 60, if they are configured as screws, can cooperate with fastening projections 70 protruding from the inner face of the housing lower part 56, and can engage in recesses 72 accordingly configured thereon in the form of threaded blind bores. Alternatively, the holding means 60 which are configured as bolts can also be fixedly connected to one of the housing parts 56, 58 which cooperate with the plug connector part 10 and, on the other respective housing part, for example the housing cover 58, can engage in recesses corresponding thereto.

FIG. 4 shows a schematic view of a vehicle 200, in particular a passenger motor vehicle 202. The vehicle 200, however, can also be configured as a utility vehicle, not shown in more detail. The vehicle 200 is provided with a control device 100, shown in FIG. 3, having a plug connector part 10 according to the disclosure. The control device 10 thus has at least one, in particular a plurality of, connector structures 34 on its plug connector part 10, which are arranged on the inner face 24 of the plug connector part 10 facing the interior 54 of the housing, and are configured to hold the plug connector part 10 in position relative to at least one, in particular both, housing parts 56, 58 via the holding means 60 which are arranged on the housing part 56, 58 or which can be connected to the housing part, in particular to the housing lower part 56.

The control device 10 can be any control unit on the vehicle 200, such as for example an engine control unit, a brake control unit or a transmission control unit.

It is understood that the foregoing description is that of the preferred embodiments of the invention and that various changes and modifications may be made thereto without departing from the spirit and scope of the invention as defined in the appended claims.

### REFERENCE SIGNS (PART OF THE DESCRIPTION)

10 Plug connector part
12 Wall portion
14 Outer face
16 Plug connector
18 Signal line
20 Wall part
22, 22′ Wall end piece
24 Inner face
26 Plug
28 Contact region
30 Periphery
32 Indentation
34 Connector structure
36 Socket
38, 38′ Side wall
40 Bottom surface
42 Reinforcing structure
44, 44′ Side edge
46 Material web
48 Terminal
50 Housing
52 Wall
54 Interior
56, 58 Housing parts, housing lower part, housing cover
60 Holding means
62, 64 Contact region
66, 66′ Material projection
68 Bolt, pin
70 Fastening projection
72 Recess
100 Control device
102, 104 Control element
106 Printed circuit board
200 Vehicle
202 Passenger motor vehicle
A Spacing
B Width dimension
H Vertical dimension

1. A plug connector part which is configured for cooperating with at least one housing part, wherein the plug connector part and the at least one housing part are configured to form a housing for a control device for vehicles, wherein the control device has a plurality of control elements which are connected together in a signal-conducting manner for controlling functions of the vehicle, the plug connector part comprising:
at least one plug connector for signal lines to be coupled thereto;
a contact region extending along at least one portion of the plug connector part and configured to connect to the at least one housing part; and,
at least one connector structure arranged on an inner face of the plug connector part which defines an interior of the housing and is configured to hold the plug connector part in position relative to the at least one housing part via retainers which are arranged on the at least one housing part or which are configured to be connected to the at least one housing part.

2. The plug connector part of claim 1 further comprising a wall portion defining a part of the housing; said wall portion including said inner face; and, said at least one plug connector being arranged on an outer face of said wall portion and said at least one connector structure being arranged on said inner face of the wall portion.

3. The plug connector part of claim 1, wherein a plurality of said at least one connector structure are arranged on said inner face of the plug connector part.

4. The plug connector part of claim 3, wherein said plurality of said at least one connector structure is configured as a holder or socket protruding from inside.

5. The plug connector part of claim 1, wherein said at least one connector structure is configured in one piece with the plug connector part.

6. The plug connector part of claim 5, wherein said at least one connector structure is injection-molded onto the plug connector part.

7. The plug connector part of claim 1, wherein the plug connector part defines a peripheral indentation with a constant width dimension along said contact region for an adhesively bonded connection to be formed with the at least one housing part.

8. The plug connector part of claim 7, wherein said indentation is configured in a groove-like manner and has two side walls extending parallel to one another over a length of said indentation at a uniform spacing.

9. The plug connector part of claim 8, wherein said indentation has a bottom surface running approximately perpendicularly to said two side walls.

10. The plug connector part of claim 9, wherein, starting from said bottom surface, an internal side wall of said two side walls has a smaller vertical dimension in comparison with an external side wall of said two side walls.

11. The plug connector part of claim 2 further comprising a reinforcing structure provided on the plug connector part.

12. The plug connector part of claim 11, wherein said reinforcing structure extends along at least one portion of a side edge of said wall portion.

13. The plug connector part of claim 11, wherein said reinforcing structure is configured as a material web receiving an indentation and protruding at least one of outside and inside laterally on said wall portion.

14. The plug connector part of claim 1, wherein the at least one housing part is made of metal or plastics.

15. The plug connector part of claim 1, wherein the control device is for vehicle components of a vehicle.

16. The plug connector part of claim 1, wherein said contact region is configured to connect to the at least one housing part for at least one of a positive connection to the at least one housing part and a sealed connection to the at least one housing part.

17. A housing for a control device for vehicles, the housing comprising:
a plug connector part;
at least one housing part configured to cooperate with said plug connector part;
said plug connector part being configured for cooperating with said at least one housing part, wherein the control device has a plurality of control elements which are connected together in a signal-conducting manner for controlling functions of the vehicle;
said plug connector part including at least one plug connector for signal lines to be coupled thereto and a contact region extending along at least one portion of the plug connector part and configured to connect to the at least one housing part;
said plug connector part further including at least one connector structure arranged on an inner face of said plug connector part which defines an interior of the housing and is configured to hold said plug connector part in position relative to said at least one housing part via retainers which are arranged on said at least one housing part or which are configured to be connected to said at least one housing part; and,
said at least one housing part has at least one retainer which cooperates with the connector structure on said plug connector part for holding the plug connector part in position relative to said at least one housing part.

18. The housing of claim 17, wherein said at least one retainer cooperates for holding the plug connector part in position relative to at least one of a housing lower part and a housing cover.

19. The housing of claim 17, wherein said at least one housing part has a projection running along said contact region and cooperating with an indentation on said plug connector part.

20. The housing of claim 17, wherein at least one of:
said at least one housing part is at least one of a housing lower part and a housing cover; and,
said at least one housing part is made of metal or plastic.

21. A control device for a vehicle, the control device comprising:
a housing including a plug connector part and at least one housing part configured to cooperate with said plug connector part;
a plurality of control elements which are connected together in a signal-conducting manner inside said housing for controlling functions of the vehicle;
said plug connector part being configured for cooperating with said at least one housing part, wherein the control device has a plurality of control elements which are connected together in a signal-conducting manner for controlling functions of the vehicle;
said plug connector part including at least one plug connector for signal lines to be coupled thereto and a contact region extending along at least one portion of the plug connector part and configured to connect to the at least one housing part;
said plug connector part further including at least one connector structure arranged on an inner face of said plug connector part which defines an interior of the housing and is configured to hold said plug connector part in position relative to said at least one housing part via retainers which are arranged on said at least one housing part or which are configured to be connected to said at least one housing part;
said at least one housing part has at least one retainer which cooperates with the connector structure on said plug connector part for holding the plug connector part in position relative to said at least one housing part.

22. The control device of claim 21, wherein said plurality of control elements are arranged on a printed circuit board.

23. The control device of claim 21, wherein the control device is for vehicle components of the vehicle.

24. A vehicle comprising:
at least one of a plug connector part, a housing, and a control device;
wherein said control device includes a housing including the plug connector part and at least one housing part configured to cooperate with said plug connector part;
said control device including a plurality of control elements which are connected together in a signal-conducting manner inside said housing for controlling functions of the vehicle;
said plug connector part being configured for cooperating with said at least one housing part, wherein the control device has a plurality of control elements which are connected together in a signal-conducting manner for controlling functions of the vehicle;
said plug connector part including at least one plug connector for signal lines to be coupled thereto and a contact region extending along at least one portion of the plug connector part and configured to connect to the at least one housing part;
said plug connector part further including at least one connector structure arranged on an inner face of said plug connector part which defines an interior of the housing and is configured to hold said plug connector part in position relative to said at least one housing part via retainers which are arranged on said at least one housing part or which are configured to be connected to said at least one housing part; and,
said at least one housing part has at least one retainer which cooperates with the connector structure on said plug connector part for holding the plug connector part in position relative to said at least one housing part.

25. The vehicle of claim 24, wherein the vehicle is a passenger motor vehicle or a utility vehicle.
